(19) United States
(12) Patent Application Publication
(10) Pub. No.: US 2019/0200468 A1
(43) Pub. Date: Jun. 27, 2019

(54) TUBULAR MOTOR FOR A CLOSURE SYSTEM

(71) Applicant: DELTA DORE, Bonnemain (FR)

(72) Inventors: Jean-Paul LEMETAYER, Bonnemain (FR); Hugues MEINRAD, Bonnemain (FR); Frédéric ROUTIER, Bonnemain (FR); Julien DUFEE, Bonnemain (FR)

(73) Assignee: Delta Dore, Bonnemain (FR)

(21) Appl. No.: 16/309,491

(22) PCT Filed: Jun. 12, 2017
(86) PCT No.: PCT/EP2017/064274

§ 371 Date: Dec. 13, 2018

(30) Foreign Application Priority Data
Jun. 15, 2016 (FR) 1655545

(51) Int. Cl. H05K 5/00; H02K 5/22; H02K 11/33; E06B 9/72

(52) U.S. Cl. CPC H05K 5/0069; H02K 5/225; H02K 11/33; E06B 2009/6809; H02K 2207/03; H02K 2211/03; E06B 9/72

(57) ABSTRACT

The invention relates to a tubular motor (200) for a shutter system that comprises:
a drive tube (106) with drive means (112) and control means (114) comprising a second connector (128) with a plurality of windows in each of which an electrical contact is arranged,
a flange (108) fixed to the drive tube (106) and having a housing (124) with holes,
a first connector (118) housed in the housing (124) and, for each hole, having a terminal (132) aligned with said hole,
a block (230) with a base (232), and, for each terminal (132), an angled pin (234) fixed to the base (232),
wherein a first end of each pin (234) is inserted in one of the windows of said second connector (128) and wherein a second end of each pin (234) is inserted in a terminal (132) through a hole.

The present invention relates to a tubular motor for a shutter system as well as a shutter system comprising such a tubular motor.

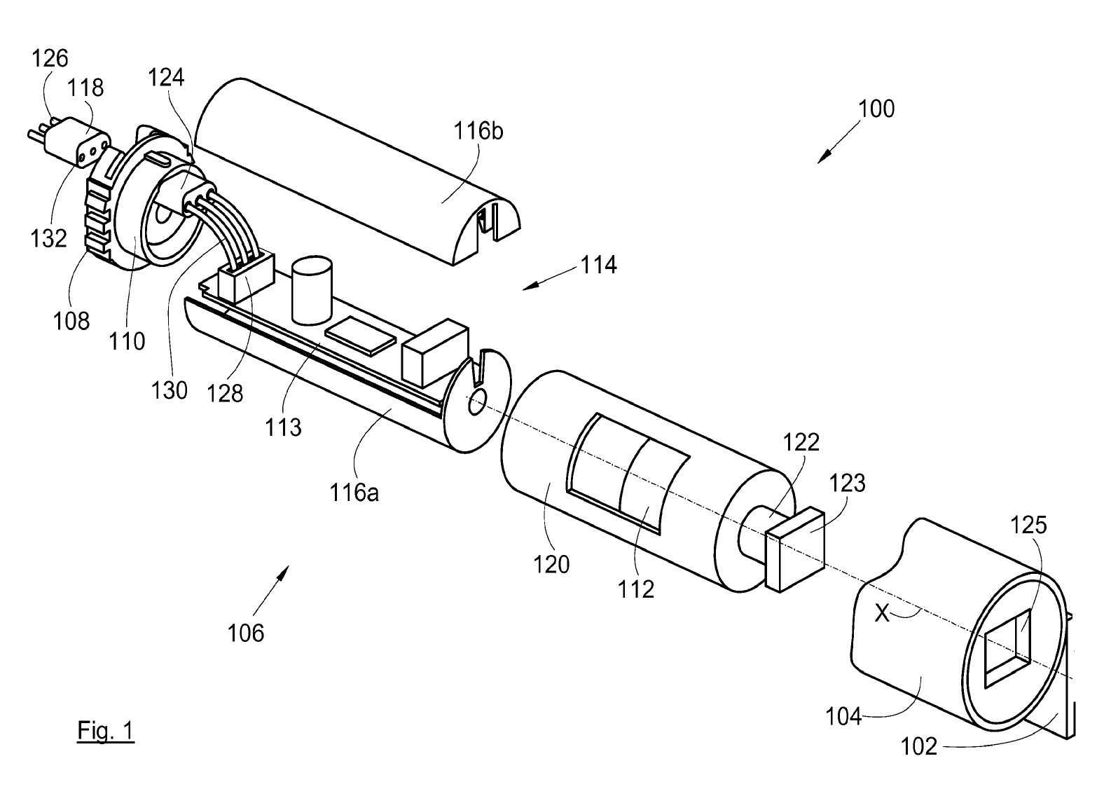

FIG. 1 shows a tubular motor 100 of the prior art for a roller blind that comprises a panel 102 fixed to a winding tube 104 of axis X and around which said panel 102 winds in order to rise. The panel 102 is fixed to the winding tube 104 by means of fixing elements. Only one end of the winding tube 104 is shown here.

The tubular motor 100 comprises a drive tube 106 comprising a tube 120 in which drive means 112 are fixed, including at least one motor, and for example also a brake and a reduction gear.

The tube 120 is coaxial with the winding tube 104 and disposed inside the latter after assembly.

The drive means 112 have a drive shaft 122 that constitutes a motor shaft driven by the motor and to the end of which a plug 123 (here a male plug) is fixed that cooperates with a socket 125 (here a female socket) of the winding tube 104. Thus the rotation of the drive shaft 122, in one direction or the other, causes the rotation of the winding tube 104 and therefore, according to the direction, the descent or rise of the panel 102.

The drive shaft 122 and the plug 123 emerge through one of the ends of the tube 120.

The tubular motor 100 also comprises a flange 108 that is mounted fixed in the box of the roller blind and a bearing 110 fixed to the flange 108 coaxial with the axis X and on which the other end of the tube 120 is fitted and fixed.

The drive tube 106 also comprises control means 114 having a printed circuit 113 and electronic components installed on the printed circuit 113, which are intended to control the motor and are enclosed here in a shell consisting here of two half-shells 116a-b fixed to one another and housed in the tube 120. The two half-shells 116a-b are fixed to the drive means 112 and to the tube 120. The printed circuit 113 is fixed in the two half-shells 116a-b and is therefore fixed with respect to the drive means 112 and to the tube 120.

The two half-shells 116a-b are positioned alongside and in line with the flange 108.

In order to provide the control and power supply of the control means 114 from the outside, the drive tube 106 also comprises a first connector 118 that is removably housed in a housing 124 of the flange 108 and comprises a plurality of terminals 132, here three in number, wherein each terminal 132 is connected to an electrical conductor 126. The electrical conductors 126 form together an electrical supply control cable that is moreover connected to an electrical power source and a control means such as a button, in order to supply and control, in rising or descent, the control means 114 and the drive means 112.

The control means 114 also comprise a second connector 128 installed on the printed circuit 113. The second connector 128 comprises a plurality of windows in each of which an electrical contact is arranged, in particular a metal leaf. Each window receives the bared end of an electrical conductor in the form of a flexible wire 130, here three in number. The other bared end of each flexible wire 130 is inserted in one of the terminals 132 through a housing hole 124. Each flexible wire 130 corresponds to an electrical conductor 126.

When the tubular motor 100 is assembled, assembly of the flexible wires 130 is manual, which may cause a delay in production and an extra cost.

One object of the present invention is to propose a tubular motor for a shutter system that does not have the drawbacks of the prior art and in particular allows robotic assembly.

To this end, a tubular motor for a shutter system is proposed, said tubular motor comprising:
a drive tube integrating drive means and control means intended to electrically control and supply the drive means;
a flange fixed to the drive tube and having a housing emerging through holes on the same side as the control means,
a first connector housed in the housing and, for each hole, having a terminal aligned with said hole,

the control means comprising a printed circuit and a second connector installed on the printed circuit and comprising a plurality of windows in each of which an electrical contact is arranged,

the tubular motor being characterised in that it also comprises a block that comprises:
a base, and
for each terminal, an angled pin fixed to the base,

wherein a first end of each pin is inserted in one of the windows of said second connector and wherein a second end of each pin is inserted in a terminal through a hole.

Advantageously, the base is disposed between the angles of the pins and the first ends that are inserted in the second connector.

Advantageously, the drive tube comprises a stop disposed opposite the windows of the second connector, and the base is arranged between the windows and the stop.

The invention also proposes a shutter system comprising:
a winding tube,
a panel fixed to the winding tube, and
a tubular motor according to one of the aforementioned variants and housed inside the winding tube.

The features of the invention mentioned above, as well as others, will emerge more clearly from a reading of the following description of an example embodiment, said description being given in relation to the accompanying drawings, among which:

FIG. 1 shows in perspective an exploded view of a tubular motor of the prior art,

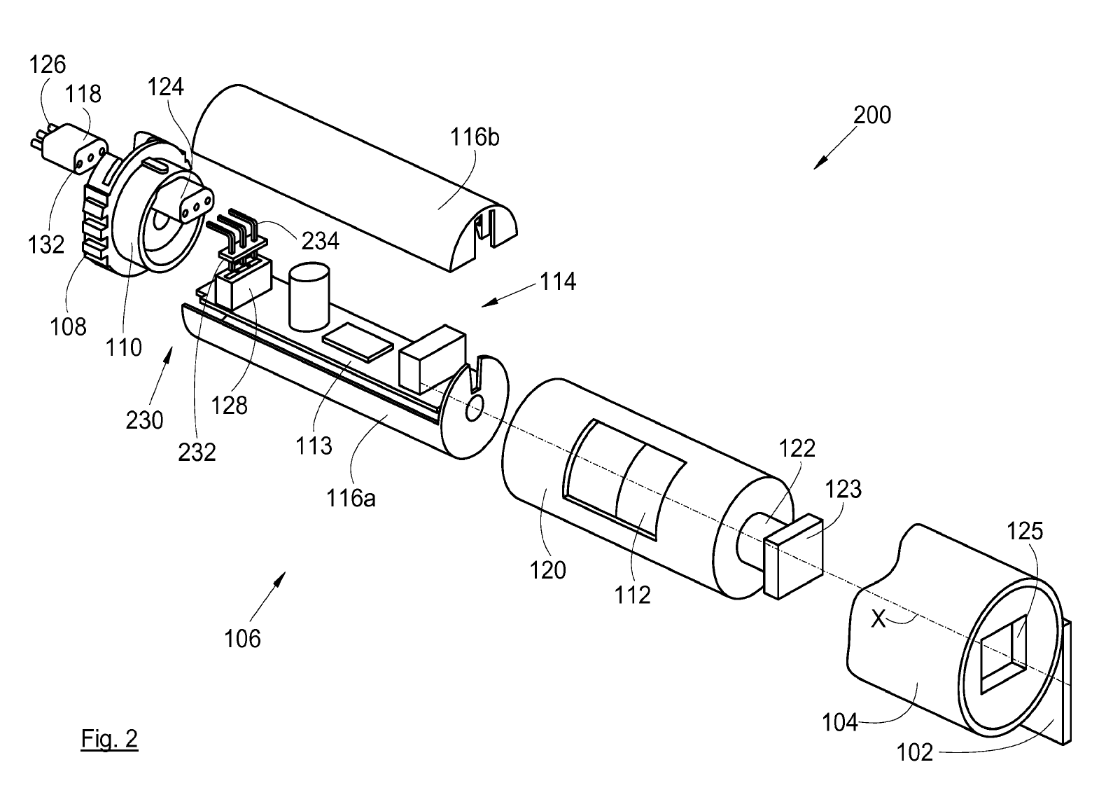

FIG. 2 shows in perspective an exploded view of a tubular motor according to the invention,

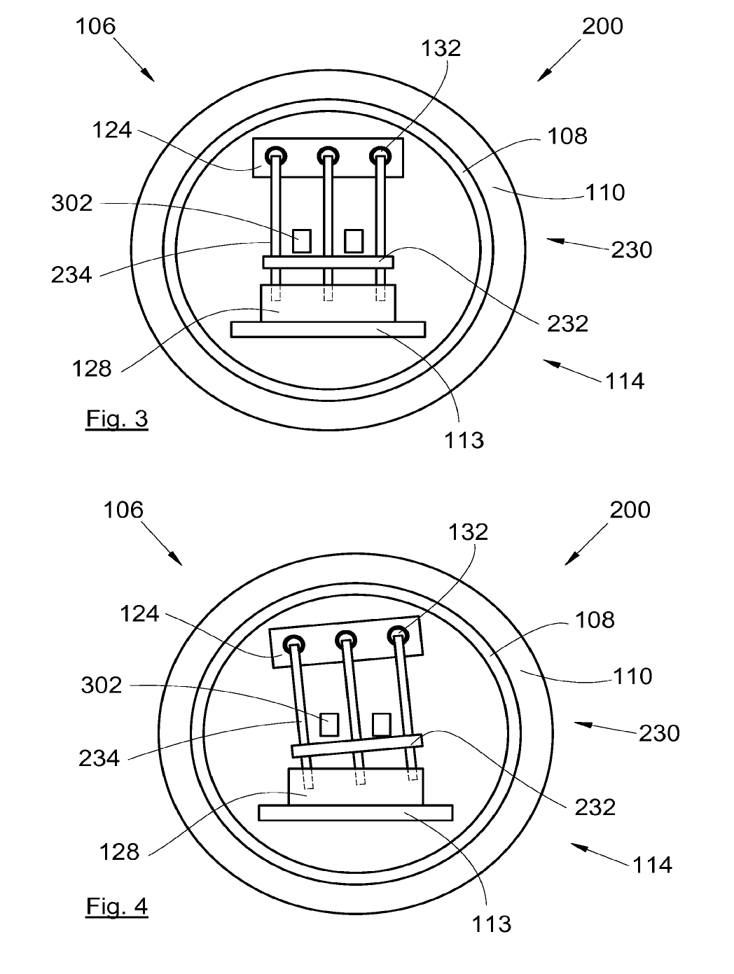

FIG. 3 shows a schematic view of a connection without angular offset, and

FIG. 4 shows a schematic view of a connection with angular offset.

FIG. 2 shows a tubular motor 200 for a roller blind similar to the one of the prior art shown in FIG. 1. The same elements therefore bear the same references and the functioning is identical except with regard to the method of connection between the first connector 118 and the second connector 128.

The roller blind thus comprises:
a winding tube 104,
a panel 102 fixed to the winding tube 104, and
a tubular motor 200 having a tube 120 housed inside the winding tube 104.

The tubular motor 200 comprises a drive tube 106 with drive means 112 that are electrically controlled and supplied by the control means 114 that are housed in a shell consisting of two half-shells 116a-b fixed to one another. The drive means 112 and the control means 114 are integrated in the drive tube 106.

The tubular motor 200 also comprises the flange 108 and the bearing 110 fixed to the flange 108. The flange 108 is fixed to the drive tube 106 by means of the bearing 110 on which the tube 120 of the drive tube 106 is fitted. The control means 114, including the printed circuit 113, are fixed to the tube 120 by means of two half-shells 116a-b that are positioned alongside and in line with the flange 108.

The flange 108 also has a housing 124 emerging through holes on the same side as the control means 114.

In order to provide the control and power supply of the control means 114 from the outside, the drive tube 106 also comprises the first connector 118, which is housed removably in the housing 124 of the flange 108 and comprises, for each hole, a terminal 132, here three in number, aligned with the hole.

Each terminal 132 is connected to an electrical conductor 126. The electrical conductors 126 form together an electrical supply and control cable that is moreover connected to an electrical power source and a control means such as a button, in order to supply and control in raising or descent the control means 114 and the drive means 112.

The control means 114 also comprise a second connector 128 installed on the printed circuit 113. The second connector 128 comprises a plurality of windows in each of which an electrical contact is disposed, in particular a metal leaf.

The tubular motor 200 also comprises a block 230 that comprises:
a base 232, and
for each terminal 132, an angled pin 234 fixed to the base 232.

The pins 132 also being secured to the base 232, the block 230 is a rigid element that can easily be manipulated by robot and can therefore be fitted in an automated fashion.

Thus, during assembly, the block 230 is placed in the second connector 128 by inserting a first end of each pin 234 in a window of said second connector 128.

Next, the flange 108 associated with the bearing 110 is placed by movement parallel to the axis X and therefore the second end of each pin 234 is inserted in a hole in the housing 124 provided for this purpose.

The first connector 118 can then be positioned in the housing 124 and each terminal 132 then receives one of the second ends of each pin 234 through one of the holes.

The other elements of the tubular motor 200 are assembled in a similar manner to those of the tubular motor 100 of the prior art. Naturally variants are possible, such as for example different forms for the male plug 123 and the female socket 125.

It is also possible to have more than three pins 234 according to the electrical commands or the information to be sent to the control means 114.

The installation in the form of two half-shells 116a-b may also be different.

FIG. 3 and FIG. 4 each show a side view of the connection between the holes of the housing 124 and therefore of the first connector 118 and the second connector 128 when the block 230 is in place.

When the tubular motor 200 is assembled, it may happen that an angular offset about the axis X exists between the control means 114 and the flange 108, and therefore more particularly between the second connector 128 and the first connector 118.

FIG. 3 shows the assembly without angular offset and FIG. 4 shows the assembly with an example of angular offset.

In FIG. 3, there is no angular offset and the first ends of each pin 234 are all pressed over the same length into the windows of the second connector 128.

In FIG. 4, there is an angular offset, which is conventionally less than 5°, and, according to the position of the pin 234, the pressing into the window of the second connector 128 may be greater or lesser.

The flexibility of the electrical contacts makes it possible to guarantee electrical contact and the dimensions of the holes make it possible to ensure penetration of each pin 234 even in the case of angular offset.

In the embodiment of the invention presented here, the base 232 is arranged between the elbows of the pins 234 and the first ends that are inserted in the second connector 128.

The base 232 thus limits the angular and linear movements allowable for the block 230, in particular because of the presence of a stop 302 that is secured to the drive tube 106 and here more precisely of the half-shell 116b and which comes above the base 232. Thus the stop 302 prevents the pins 234 coming out of the second connector 128 because the base 232 abuts under the stop 302.

Thus, in general terms, the drive tube 106 comprises the stop 302, which is arranged opposite the windows of the second connector 128, and so that the base 232 is arranged between the windows and the stop 302.

Preferentially, the stop 302 is at a maximum of 2 mm from the base 232.

The invention applies in the same way to any shutter system comprising a winding system and a windable panel, such as for example an awning, a coilable screen, an indoor blind or a garage door.

1. Tubular motor (200) for a shutter system, said tubular motor (200) comprising:
a drive tube (106) integrating drive means (112) and control means (114) intended to electrically control and supply the drive means (112);
a flange (108) fixed to the drive tube (106) and having a housing (124) emerging through holes on the same side as the control means (114),
a first connector (118) housed in the housing (124) and, for each hole, having a terminal (132) aligned with said hole,
the control means (114) comprising a printed circuit (113) and a second connector (128) installed on the printed circuit (113) and comprising a plurality of windows in each of which an electrical contact is arranged,
the tubular motor (200) being characterised in that it also comprises a block (230) that comprises:
a base (232), and
for each terminal (132), an angled pin (234) fixed to the base (232),
wherein a first end of each pin (234) is inserted in one of the windows of said second connector (128) and wherein a second end of each pin (234) is inserted in a terminal (132) through a hole.

2. Tubular motor (200) according to claim 1, characterised in that the base (232) is disposed between the angles of the pins (234) and the first ends that are inserted in the second connector (128).

3. Tubular motor (200) according to claim 2, characterised in that the drive tube (106) comprises a stop (302) disposed opposite the windows of the second connector (128), and in that the base (232) is arranged between the windows and the stop (302).

4. Shutter system comprising:
a winding tube (104),
a panel (102) fixed to the winding tube (104), and
a tubular motor (200) according to any of the preceding claims and housed inside the winding tube (104).
